(19) United States
(12) Patent Application Publication
(10) Pub. No.: US 2006/0051885 A1
(43) Pub. Date: Mar. 9, 2006

(54) Method of fabricating mask of gate electrode of field-emission display

(76) Inventors: Jui-Ting Hsu, Guanyin Township (TW); Jia-Hung Wu, Guanyin Township (TW); Pu-Hsin Chang, Guanyin Township (TW); Shih-Hsun Chen, Guanyin Township (TW); Shih-Chien Hsiao, Guanyin Township (TW)

Correspondence Address: Yi-Wen Tseng, 4331 Stevens Battle Lane, Fairfax, VA, 22033, US

(21) Appl. No.: 10/934,592

(22) Filed: Sep. 3, 2004

(51) Int. Cl. H01L 21/00

(52) U.S. Cl. 438/20

(57) ABSTRACT

A method of fabricating a gate mask of a tetra-polar field-emission display. A focus metal mask having a plurality of windows is formed. A low-viscosity and water-soluble high molecular solution is coated on the focus metal mask to form a viscous interface. A first low-temperature drying process is performed allow the viscous interface dried up into a film. An insulating material is then formed on the film of viscous interface by screen printing. A sintering process is performed to remove the viscous interface, so as to crystallize the insulating material on the focus metal mask.

### BACKGROUND OF THE INVENTION

The present invention relates in general to a method of fabricating a mask of gate electrode, and more particularly, to a method for forming a viscous interface on a focus metal mask of a tetra-polar field-emission display to allow insulating coating material easily applied thereon. The viscous interface also avoids the insulating coating material flowing into windows of the focus metal mask.

FIG. 1 shows a conventional tetra-polar field-emission display, which includes a converging electrode layer (focus metal mask) 42 over the gate electrode 41 of the cathode electrode 4 and under the anode electrode 5. The converging electrode layer 42 formed between anode electrode 5 and the cathode electrode 4 provides converging effect of the electron beams propagating from the cathode electrode 4 to the anode electrode 5.

The converging electrode layer 42 is combined with the gate electrode 41 to form a sandwich structure, which allows a simplified packaging process with a higher yield and lower cost. Such converging electrode layer 42 includes an insulating layer 43 coated or screen printed on a gate mask, and a gate electrode layer 41 formed on the insulating layer 43. Photolithography and etching process is then performed to form the corresponding windows 44 allowing electron beams to propagate through, so as to excite the phosphor layer of the anode electrode. Thereby, a tetra-polar structure is formed.

The above converging layer 42 is an alloy having an expansion coefficient similar to that of glass material, while the insulating layer 43 is fabricated from organic coating material containing glass material. The process for forming the insulating layer 43 is a non-contact coating, or a roller press process to coat a film of the insulating layer 43 on the mask, followed by a sintering step to crystallize and attach the glass material contained in the organic coating material on the converging electrode layer 42. Should the organic coating material be directly coated on the converging electrode 42, the follow problems occur.

1. The material differences make it difficult to coat the organic coating material into a film on the converging electrode layer 42.

2. The organic coating material on the converging electrode layer 42 surrounding the windows 44 easily flows into the window 44 to cause uneven thickness of the film around the windows 44. Therefore, the selection of material for forming the insulating layer 43 and the converging electrode layer 42 is further limited.

### BRIEF SUMMARY OF THE INVENTION

To resolve the above drawbacks, a method for preventing the insulating layer from flowing into the window is provided. The deformation of the insulating layer around the window is thus prevented from affecting fabrication of the gate electrode layer.

The method as provided includes the following steps. A focus metal mask having a plurality of windows is formed. A low-viscosity and water-soluble high molecular solution is coated on the focus metal mask to form a viscous interface. A first low-temperature drying process is performed allow the viscous interface dried up into a film. An insulating material is then formed on the film of viscous interface by screen printing. A sintering process is performed to remove the viscous interface, so as to crystallize the insulating material on the focus metal mask.

### BRIEF DESCRIPTION OF THE DRAWINGS

The above objects and advantages of the present invention will be become more apparent by describing in detail exemplary embodiments thereof with reference to the attached drawings in which:

FIG. 1 shows a conventional tetra-polar field-emission display;

FIG. 2 shows a structure of a focus metal mask;

FIG. 3 shows the focus metal mask coated with a viscous interface;

FIG. 4 shows the viscous interface coated with an insulating material;

FIG. 5 shows the removal of the viscous interface by a sintering process; and

FIG. 6 shows a temperature setup of a sintering furnace.

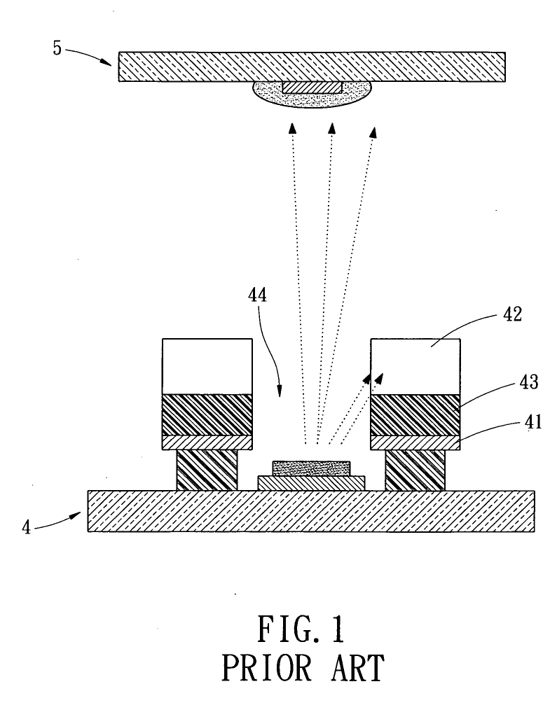

### DETAILED DESCRIPTION OF THE INVENTION

The method of fabricating the gate mask as provided is applicable for tetra-polar field-emission display. In this method, a viscous interface is formed on a focus metal mask to allow the insulating material easily coated thereon, so as to avoid the insulating material flowing into the window of the focus metal mask. Therefore, a uniform insulating layer can be obtained. The viscous interface is fabricated from a material that can be easily removed by sintering process, such that the recrystallized insulating material can be secured to the metal mask.

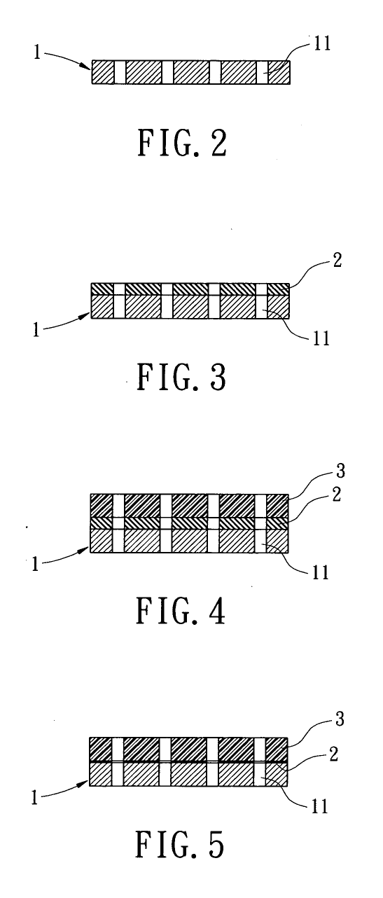

Referring to FIGS. 2 to 5, a process flow of the focus mask and the insulating layer is showed. A focus metal mask 1 made of alloy having an expansion coefficient similar to that of glass is provided. A plurality of windows 11 is formed within the focus metal mask 1.

A spin-coating process is performed to form a film of viscous interface 2 on the focus metal mask 1. The material of the viscous interface 2 includes water solution of polyvinyl alcohol (PVA) with a weight percentage between 2% to 6%, preferably 4% or a 4% PVP solution.

A drying step is the performed at a temperature as low as 60° C., such that a film of the viscous interface 2 is formed.

An insulating material such as Dupont DG001 is formed on the film of viscous interface 2. Preferably, the insulating material is formed by screen printing or non-contact coating process. The insulating material includes an organic coating material containing glass, for example.

A second step of low-temperature drying steps is performed after the insulating layer 3 is coated. The temperature for such drying step is about 80° C. to 90° C., for example. A sintering process is then performed to remove the film of viscous interface 2, so as to crystallize the insulating layer 3 affixed on the focus metal mask 1. The gate electrode layer is formed in subsequent steps.

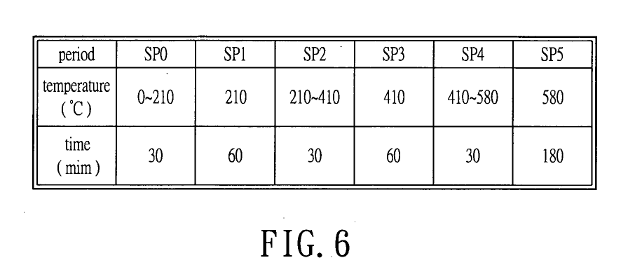

FIG. 6 shows the temperature setup of the sintering furnace. As shown, the temperature of the sintering furnace is rising from 0° C. to 210° C. within 30 minutes in SP0 period. The sintering furnace is then maintained at 210° C. for about 60 minutes in SP1 period, such that the water solution or low-molecular interface is removed by vaporization. It is important to increase the temperature as smooth as possible to avoid bubble generated by vaporization of the low-molecular material and peeling of the insulating layer 3. The temperature is then increased up to 410° C. within 30 minutes in SP2 period, and maintained for about 60 minutes in SP3 period to remove high-molecular portion of the viscous interface. The temperature is then increased to 580° C. within 30 minutes in SP4 period, and maintained for about 3 hours in SP5 period, such that the glass contained in the insulating layer 3 is crystallized on the focus metal mask 1.

The formation of the viscous interface between the insulating layer 3 and the focus metal mask 1 allows the insulating layer 3 easily applied to the focus metal mask 1, such that more variety of materials can be selected for forming the insulating layer 3 and the focus metal mask 1.

The viscous interface 2 also prevents the insulating material from flowing into the window of the focus metal mask 1, such that a uniform insulating layer can be obtained.

The viscous interface 2 is fabricated from a material which is low-cost and easily obtained. More importantly, the viscous interface 2 can be easily removed without additional process.

While the present invention has been particularly shown and described with reference to preferred embodiments thereof, it will be understood by those of ordinary skill in the art the various changes in form and details may be made therein without departing from the spirit and scope of the present invention as defined by the appended claims.

What is claimed is:

1. A method of fabricating a gate mask, comprising:
forming focus metal mask having a plurality of windows therein;
forming a film of viscous interface on the focus metal mask from a water solution of low-viscous polymer;
forming an insulating layer on the film of viscous interface; and
performing a sintering process.

2. The method of claim 1, wherein the focus metal mask is formed of an alloy having an expansion coefficient similar to that of glass.

3. The method of claim 1, wherein the water solution of low-viscous polymer has a weight percentage of about 2% to about 6%.

4. The method of claim 3, wherein the water solution of low-viscous polymer has a weight percentage of about 4%.

5. The method of claim 1, wherein the low-viscous polymer is selected from a polymer removable by the sintering process.

6. The method of claim 1, wherein the low-viscous polymer includes polyvinyl alcohol.

7. The method of claim 1, wherein the low-viscous polymer includes PVP.

8. The method of claim 1, wherein the insulating layer includes an organic material containing glass.

9. The method of claim 1, further comprising a first drying step performed on the film of viscous interface.

10. The method of claim 9, wherein the first drying step is performed at about 60° C.

11. The method of claim 9, further comprising a second drying step performed on the insulating layer.

12. The method of claim 11, wherein the second drying step is performed at about 80° C. to 90° C.

13. The method of claim 1, wherein the sintering step includes a first stage maintained at a temperature of about 210° C. for about an hour.

14. The method of claim 13, wherein the sintering step includes a second stage maintained at a temperature of about 410° C. for about an hour.

15. The method of claim 14, wherein the sintering step includes a third stage maintained at a temperature about 580° C. for about 3 hours.

16. A method for fabricating a gate mask for a tetra-polar field-emission display, comprising:
providing a focus metal mask having at least a window therein;
forming a film of viscous interface on the focus metal mask; and
applying an insulating material on the film of viscous interface, wherein the film of viscous interface is fabricated from a material operative to prevent the insulating material from flowing into windows of the focus metal mask; and
removing the film of viscous interface from and bonding the insulating material to the focus metal mask.

17. The method of claim 16, wherein the material for forming the film of viscous interface includes applying a solution of low-viscous polymer solution.

18. The method of claim 16, wherein the step of removing the film of viscous interface includes a sintering stage at about 210° and a sintering stage at about 410° C.

19. The method of claim 16, wherein the step of bonding the insulating material includes a sintering stage at about 580° C.

20. The method of claim 16, wherein the insulating material is selected from an organic material containing glass.

21. The method of claim 20, wherein the step of bonding the insulating material on the focus metal mask further comprises crystallize the glass contained therein.
